(19) United States
(12) Patent Application Publication
(10) Pub. No.: US 2015/0187562 A1
(43) Pub. Date: Jul. 2, 2015

(54) ABATEMENT WATER FLOW CONTROL SYSTEM AND OPERATION METHOD THEREOF

(71) Applicant: TAIWAN SEMICONDUCTOR MANUFACTURING COMPANY LTD., HSINCHU (TW)

(72) Inventors: HENG-MING LEE, HSINCHU CITY (TW); YUNG-TI HUNG, HSINCHU CITY (TW); NAN-HSIUNG HUNG, HSIN-CHU CITY (TW)

(73) Assignee: TAIWAN SEMICONDUCTOR MANUFACTURING COMPANY LTD., HSINCHU (TW)

(21) Appl. No.: 14/142,703

(22) Filed: Dec. 27, 2013

(51) Int. Cl. H01L 21/02; H01L 21/67

(52) U.S. Cl. CPC H01L 21/02057; H01L 21/67242; H01L 21/67017

(57) ABSTRACT

A system including a water flow controller arranged to transmit electrical signals between a fluoride ion clean tool and a fluoride emission abatement system is provided. Fluoride gas is configured to be released from the fluoride ion clean tool and lead to the fluoride emission abatement system, and water is introduced to the fluoride emission abatement system so as to process the fluoride gas. The water flow controller further includes a receiver for accepting electrical signals from a detector. The detector is configured to measure a flow rate of fluoride gas introduced to the fluoride ion clean tool. In addition, a computing unit is configured to process electrical signals from the detector. A transmitter is configured to send commands to an actuator of the fluoride emission abatement system so as to adjust water introduced to the fluoride emission abatement system based on a processing result of the computing unit.

### FIELD

The present disclosure relates to an abatement water flow control system and operation method thereof.

### BACKGROUND

In the semiconductor production industry, various processing steps are used to fabricate integrated circuits on a semiconductor wafer. These steps include the deposition of layers of different materials including metallization layers, passivation layers and insulation layers on the wafer substrate, as well as photoresist stripping and sidewall passivation polymer layer removal. In modern memory devices, for example, multiple layers of metal conductors are required for providing a multi-layer metal interconnection structure in defining a circuit on the wafer. Chemical vapor deposition (CVD) processes are widely used to form layers of materials on a semiconductor wafer.

CVD processes include thermal deposition processes, in which a gas is reacted with the heated surface of a semiconductor wafer substrate, as well as plasma-enhanced CVD processes, in which a gas is subjected to electromagnetic energy in order to transform the gas into a more reactive plasma. However, in plasma process chambers used to carry out these various CVD processes, materials such as polymers are coated onto the chamber walls and other interior chamber components and surfaces during the processes. These polymer coatings frequently generate particles which inadvertently become dislodged from the surfaces and contaminate the wafers.

To remove the residue materials from the chamber walls, cleaning gases, such as fluorocarcon gases, are used. During the cleaning process, the F ions will be recomposed into F2, SiF4, COF2 or other fluoride compounds. However, fluoride compounds are known pollutants. For example, fluoride compounds diffuse undesirable odor. Moreover, fluoride compounds exert a considerable global warming potential (GWP) effect on the environment. Increasingly, governments and international treaties are requiring that the venting of high-GWP chemicals be reduced or eliminated. Measures to reduce fluoride compound contaminations on the environment are continuously being sought.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIG. 1 is a system including a water flow controller in accordance with some embodiments of the present disclosure.

FIGS. 2A to 2C are systems including a water flow controller in accordance with some embodiments of the present disclosure.

FIG. 3 illustrates communications between components in a system including a water flow controller in accordance with some embodiments of the present disclosure.

FIG. 4 is a flow diagram of a method for manufacturing semiconductor wafer in accordance with some embodiments of the present disclosure.

FIGS. 5A to 5D are behavioral views of an apparatus in various stages corresponding to the method of FIG. 4.

Like reference symbols in the various drawings indicate like elements.

### DETAILED DESCRIPTION OF THE DISCLOSURE

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure.

Throughout the various views and illustrative embodiments, like reference numerals are used to designate like elements. Reference will now be made in detail to exemplary embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, an apparatus in accordance with the present disclosure. It is to be understood that elements not specifically shown or described may take various forms. Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

In the drawings, like reference numbers are used to designate like or similar elements throughout the various views, and illustrative embodiments of the present disclosure are shown and described. The figures are not necessarily drawn to scale, and in some instances the drawings have been exaggerated and/or simplified in places for illustrative purposes. One of ordinary skill in the art will appreciate the many possible applications and variations of the present disclosure based on the following illustrative embodiments of the present disclosure.

It will be understood that when an element is referred to as being “on” another element, it can be directly on the other element or intervening elements may be present. In contrast, when an element is referred to as being “directly on” another element, there are no intervening elements present.

It will be understood that singular forms “a”, “an” and “the” are intended to include the plural forms as well, unless the context clearly indicates otherwise. Furthermore, relative terms, such as “bottom” and “top,” may be used herein to describe one element's relationship to other elements as illustrated in the Figures.

It will be understood that elements described as “under” or “below” other elements would then be oriented “over” or “above” the other elements. The exemplary terms “under” or “below” can, therefore, encompass both an orientation of over and under.

Unless otherwise defined, all terms (including technical and scientific terms) used herein have the same meaning as commonly understood by one of ordinary skill in the art to which this disclosure belongs. It will be further understood that terms; such as those defined in commonly used dictionaries, should be interpreted as having a meaning that is consistent with their meaning in the context of the relevant art and the present disclosure, and will not be interpreted in an idealized or overly formal sense unless expressly so defined herein.

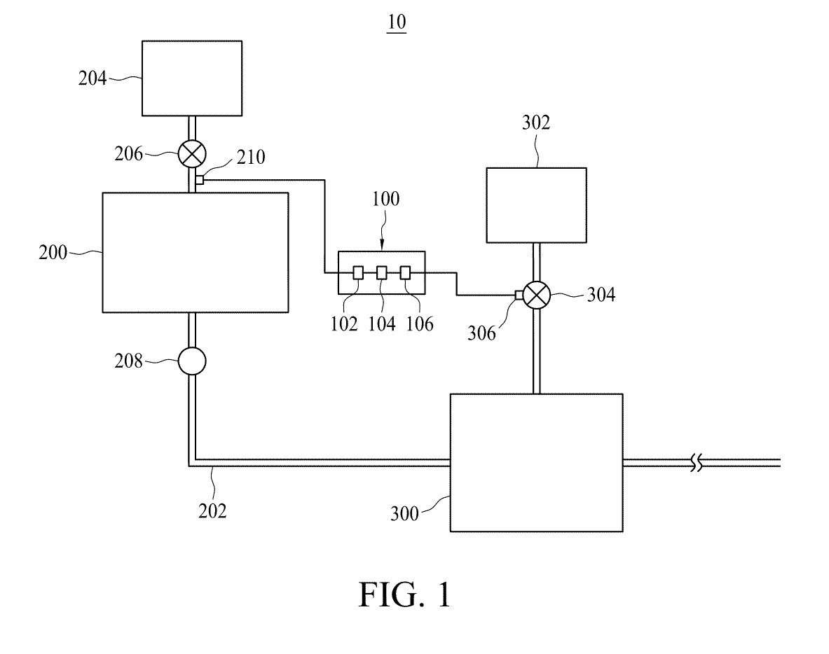

FIG. 1 is a system including a water flow controller in accordance with some embodiments of the present disclosure.

Referring to FIG. 1, a system 10 including a water flow controller 100 is provided. In some embodiments, the system 10 is a semiconductor wafer process system. In certain embodiments, the system 10 is an integrated circuit process system, a liquid-crystal display process system or a light-emitting diode process system. The water flow controller 100 is configured to adjust water distribution in the system 10 for numerous processes. For example, water is introduced to the system 10 for a chemical vapor deposition (CVD) process. Alternatively, the water flow controller 100 is applicable in processes used in the fabrication of integrated circuits or semiconductor wafer substrates.

In some embodiments in accordance with the present disclosure, the water flow controller 100 has a receiver 102 connected with a computing unit 104. In addition, the computing unit 104 is connected with a transmitter 106. The receiver 102 accepts electrical signals from a sensor or detector wirelessly or through a physical interface. The signals indicate an operation condition of the system 10. The computing unit 104 receives the electrical signals from the receiver 102 and processes such electrical signals. For example, the computing unit 104 extracts a value from the electrical signal and compares such value with a predetermined value. Based on the comparison result, the computing unit 104 sends a command to another device in the system 100 through the transmitter 106 wirelessly or through a physical interface. In some embodiments, the command sent by the computing unit 104 serves to adjust water distribution in the system 10.

In some embodiments in accordance with the present disclosure, the computing unit 104 is a general purpose microprocessor known in the art. For example, the computing unit 104 includes an application-specific integrated circuit (ASIC), reduced instruction set processor (RISC), or programmable logic controller (PLC). In another example, the computing unit 104 is a central processing unit (CPU) or a microprocessor.

In some embodiments in accordance with the present disclosure, the system 10 includes a fluoride ion clean tool 200 connected with a fluoride emission abatement system 300 through a foreline 202. In certain embodiments, the fluoride ion clean tool 200 includes a chemical vapor deposition (CVD) process chamber. During normal operation of the fluoride ion clean tool 200, material residues gradually accumulate on the interior surfaces of the fluoride ion clean tool 200. The material residues include silicon nitride and silicon dioxide, for example. Particles from the residues have a tendency to break off and potentially contaminate devices being fabricated on subsequent wafers processed in the fluoride ion clean tool 200. Accordingly, the particles are arranged to be periodically removed from the interior surfaces of the fluoride ion clean tool 200 for optimum processing. During clean operation of the fluoride ion clean tool 200, fluoride compound gas (alternatively “fluoride gas”), or fluoride ion is introduced to the fluoride ion clean tool 200 to react with the particles. Exhaust fluoride gas, such as F2, NF3, C2F6, SiF4 or the like, is generated and lead to the fluoride emission abatement system 300 through the foreline 202. Water is provided at the fluoride emission abatement system 300 to react with the exhaust fluoride gas so as to reduce the amount of fluoride compound being released to the environment.

In some embodiments in accordance with the present disclosure, the fluoride ion clean tool 200 is connected with a gas source 204 for containing fluoride gas to be introduced to the fluoride ion clean tool 200. A valve 206 is arranged between the fluoride ion clean tool 200 and the gas source 204 to control the fluoride gas output flow. In some embodiments, the fluoride gas includes F2, NF3, C2F6 or SiF4. In certain embodiments, an actuator of the valve 206 is connected to a central control unit (not depicted) of the system 10. Accordingly, the valve is configurable by the central control unit depending on the condition of the system 10. For example, the amount of fluoride gas introduced to the fluoride ion clean tool 200 is adjusted based on the condition of the system 10.

In some embodiments in accordance with the present disclosure, the fluoride ion clean tool 200 is or is part of a semiconductor wafer process tool, an integrated circuit process tool, a liquid-crystal display process tool or a light-emitting diode process tool.

In some embodiments in accordance with the present disclosure, a pump 208 is arranged between the fluoride ion clean tool 200 and the fluoride emission abatement system 300. The pump 208 serves to provide a suction force to lead fluoride gas out of the fluoride ion clean tool 200 and into the fluoride emission abatement system 300. In some embodiments, the pump 208 continues to generate a suction force. In certain embodiments, the pump 208 is equipped with an actuator, and the actuator is configured to receive commands from the central control unit of the system 10. Accordingly, the suction force generated by the pump 208 is adjustable based on the condition of the system 10. In some embodiments, the pump 208 is a dry pump.

In some embodiments in accordance with the present disclosure, the fluoride emission abatement system 300 is connected with a water source 302. Water (H2O) is provided from the water source 302 through a valve 304 to the fluoride emission abatement system 300. In certain embodiments, water is used to interact with fluoride gas so as to turn fluoride gas into liquid HF. Accordingly, the amount of fluoride gas released to the environment is lessened. In some embodiments, water is introduced to the fluoride emission abatement system 300 continuously. In certain embodiments, the fluoride emission abatement system 300 is a scrubber.

In some embodiments in accordance with the present disclosure, the amount of water introduced to the fluoride emission abatement system 300 is adjustable by the valve 304. The valve is equipped with an actuator 306. The actuator 306 is configured to receive commands, which are based on the processing result of the computing unit 104, from the transmitter 106 of the water flow controller 100. Depending on the operation condition of the system 10 or the fabrication plant facilitating the system 10, the computing unit 104 sends out different commands to the actuator 306 so as to adjust the valve 304.

In some embodiments in accordance with the present disclosure, electrical signals are transmitted between the fluoride ion clean tool 200 and the fluoride emission abatement system 300 through the water flow controller 100. For example, signal of the processing status of the fluoride ion clean tool 200 is transmitted to the water flow controller 100. After processing the signal, the water flow controller 100 sends a command to the fluoride emission abatement system 300. Accordingly, the fluoride emission abatement system 300 adjusts its processing status in response to the command from the water flow controller 100. In certain embodiments, when the fluoride ion clean tool 200 is in normal operation, the fluoride emission abatement system 300 reduces its processing rate due to the lessened output of fluoride gas from the fluoride ion clean tool 200.

In some embodiments in accordance with the present disclosure, a detector 210 is provided in the system 10. The detector 210 is configured to measure a flow rate of fluoride compound, such as the fluoride gas, introduced to the fluoride ion clean tool 200. Thereafter, the detector 210 sends electronic signals containing the information of the flow rate to the receiver 102. The computing unit 104 is configured to process such electronic signals received from the detector 210. For example, the computing unit 104 compares the flow rate with a predetermined value. If the flow rate is above the predetermined value, the computing unit 104 determines that the fluoride ion clean tool 200 is in a clean operation. A command to increase water introduction is generated and sent through the transmitter 106 to the actuator 306. Accordingly, the actuator 306 adjusts the valve 304 so as to increase water introduction to the fluoride emission abatement system 300. The increased amount of water reduces the chance of fluoride gas being released to the environment.

In some embodiments in accordance with the present disclosure, when the fluoride gas is being introduced to the fluoride ion clean tool 200 at a first flow rate, the water flow controller 100 adjusts the water introduction to the fluoride emission abatement system 300 at a first water flow rate. In addition, when the fluoride gas is being introduced to the fluoride ion clean tool 200 at a second flow rate, the water flow controller 100 adjusts the water introduction to the fluoride emission abatement system 300 at a second water flow rate. When the first flow rate is higher than the second flow rate, the first water flow rate is higher than the second water flow rate. In other words, when fluoride gas is introduced to the fluoride ion clean tool 200 at a higher flow rate, i.e., when the fluoride ion clean tool 200 is in the clean operation, more water is introduced to the fluoride emission abatement system 300 to process the fluoride gas. Contrarily, when fluoride gas is introduced to the fluoride ion clean tool 200 at a lower velocity, i.e., when the fluoride ion clean tool 200 is in the normal operation, less water is needed at the fluoride emission abatement system 300. In certain embodiments, water is introduced to the fluoride emission abatement system 300 at a flow rate between about 8 LPM (liter per minute) and about 12 LPM when the when the fluoride ion clean tool 200 is in the clean operation. In addition, water is introduced to the fluoride emission abatement system 300 at a flow rate between about 0 LPM and about 5 LPM when the when the fluoride ion clean tool 200 is in the normal operation.

In some embodiments in accordance with the present disclosure, the detector 210 is disposed between the gas source 204 and the fluoride ion clean tool 200. For example, the detector 210 is disposed at the valve 206. Alternatively, the detector 210 is disposed at the pump 208, the foreline 202, or the fluoride ion clean tool 200 itself. In certain embodiments, the detector is a flow meter at the fluoride emission abatement system 300 so as to detect the flow rate of fluoride gas introduced to the fluoride emission abatement system 300.

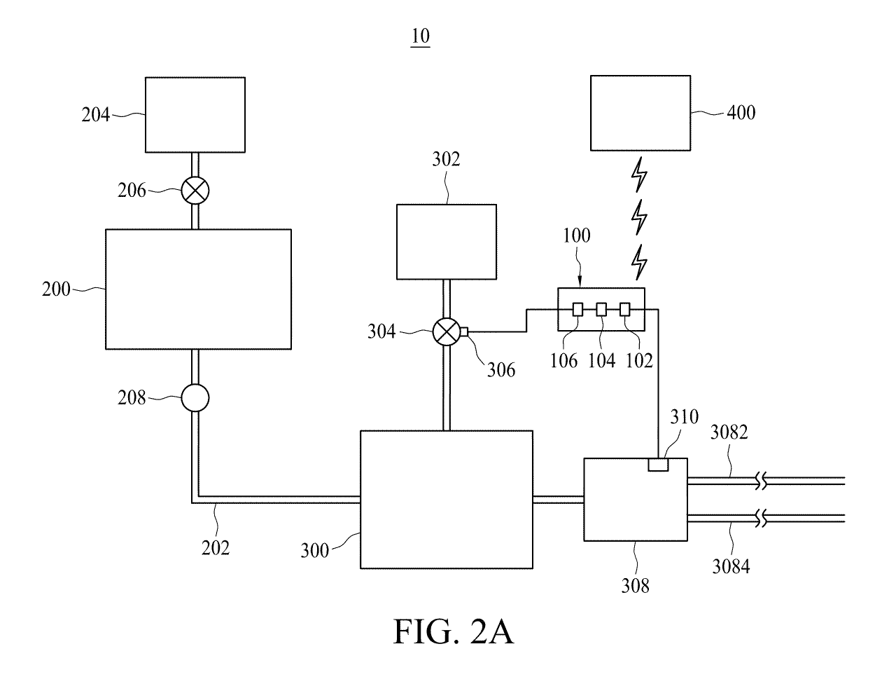

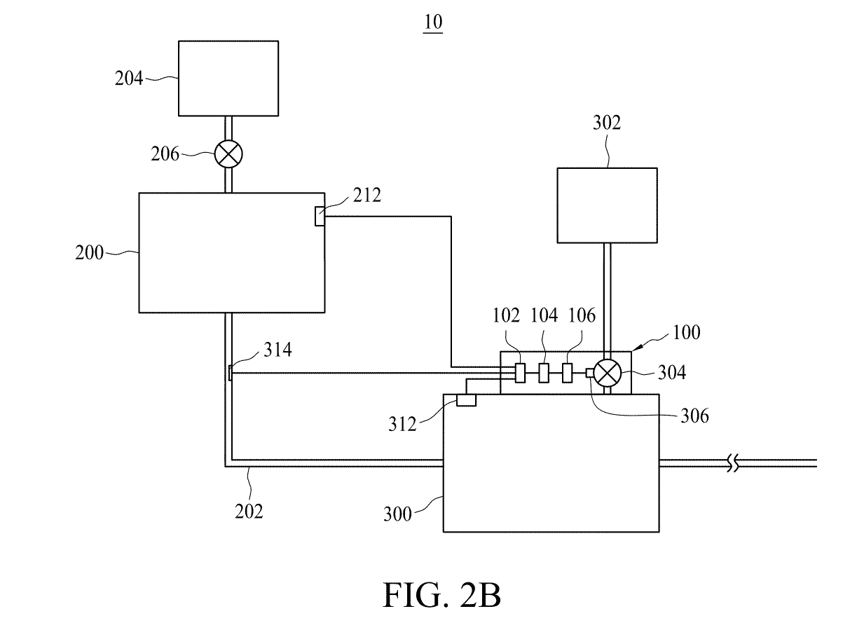

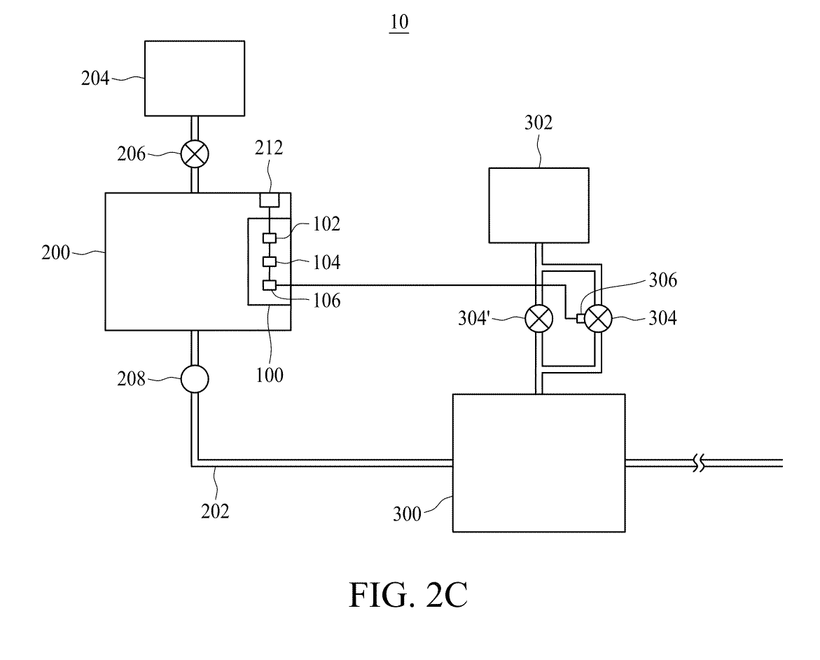

FIGS. 2A to 2C are systems including a water flow controller in accordance with some embodiments of the present disclosure.

Referring to FIG. 2A, in some embodiments, the water flow controller 100 is configured to receive electrical signals from a central control unit 400 of the fabrication plant facilitating the system 10. Alternatively, the water flow controller 100 is connected with a central control unit 400 so as to receive the signal. The signal transmitted from the central control unit 400 contains the condition of the fabrication plant, or processing status of other process tools within the fabrication plant. An exemplary process tool is a semiconductor wafer processing tool. The computing unit 104 of the water flow controller 100 receives the signal via the receiver 102 and processes the signal. Depending on the conditions transmitted, the computing unit 104 generates commands to be transmitted to the actuator 306 through the transmitter 106. Accordingly, water introduction to the fluoride emission abatement system 300 is manipulated based on the commands. For example, when another process tool in the fabrication plant requests more water, water introduction to the fluoride emission abatement system 300 is lessened. In certain embodiments, in response to the water decrease, the water flow controller 100 is configured to send a command to a mass flow controller (MFC) of the fluoride ion clean tool 200 so as to reduce fluoride gas from being introduced to the fluoride ion clean tool 200.

In some embodiments in accordance with the present disclosure, the central control unit 400 is a manufacturing execution system (MES) at the fabrication plant. The manufacturing execution system monitors all the operations in fabrication plants, and relays messages to the sub-control systems, such as system 10, to maintain smooth cooperation between systems.

In some embodiments in accordance with the present disclosure, the fluoride emission abatement system 300 is connected with a waste processor 308. The waste processor 308 receives exhaust fluoride compound and/or exhaust water from the fluoride emission abatement system 300 and performs further processing. For example, the waste processor separates the exhaust fluoride compound and the exhaust water and outputs them to the environment through different forelines 3082, 3084 to reduce contamination. In some embodiments, the waste processor 308 has a detector 310. The detector 310 measures the concentration of fluoride compound at the waste processor 308 and transmits such information in the form of electrical signal to the receiver 102. The processor 104 compares such concentration with a predetermined value and determines whether a specific event has occurred. For example, a concentration of fluoride compound over a predetermined value indicates that the fluoride ion clean tool 200 is in a clean operation. Accordingly, the processor 104 sends a command to the actuator 306 through the transmitter 106 to adjust water introduction to the fluoride emission abatement system 300. In certain embodiments, water introduction to the fluoride emission abatement system 300 is increased when the fluoride ion clean tool 200 is in a clean operation. In some embodiments, water introduction to the fluoride emission abatement system 300 is decreased when the fluoride ion clean tool 200 is in an idle mode.

In some embodiments in accordance with the present disclosure, water introduction to the fluoride emission abatement system 300 is adjusted according to a gas flow rate detected at the waste processor 308. For example, the detector 310 is a flow meter for detecting fluoride compound gas flow rate at the waste processor 308. The flow rate information is transmitted to the processor 104 and compared with a predetermined value. In certain embodiments, if the fluoride compound gas flow rate is below a predetermined value, the processor 104 sends a command to the actuator 306 through the transmitter 106 and decreases water introduction to the fluoride emission abatement system 300.

Referring to FIG. 2B, in some embodiments, the system 10 includes a sensor for detecting ambient condition in the system 10. For example, the sensor 312 is a pressure sensor arranged at the fluoride emission abatement system 300. The sensor 312 detects a pressure in the fluoride emission abatement system 300 and transmits such information to the water flow controller 100. The processor 104 receives such information through the receiver 102. A processing result is acquired to be used to control the actuator 306 so as to manipulate the valve 304. Accordingly, water introduction to the fluoride emission abatement system 300 is adjusted based on the pressure in the fluoride emission abatement system 300. In some embodiments, a higher pressure in the fluoride emission abatement system 300 indicates that that the fluoride ion clean tool 200 is in the clean mode. Therefore, more water is introduced to the fluoride emission abatement system 300 to process the fluoride gas.

In some embodiments in accordance with the present disclosure, the sensor 212 is a chemical sensor arranged at the fluoride ion clean tool 200. The sensor 212 detects concentration of fluoride gas at the fluoride ion clean tool 200. The fluoride gas includes, but is not limited to, F2, NF3, C2F6, and SiF4. The sensor 212 transmits the detected concentration information to the processor 104 through the receiver 102. The processor 104 compares the concentration with a predetermined value to determine the operation mode of the fluoride ion clean tool 200. Based on the processing result, the actuator 306 of the valve 304 is manipulated so as to adjust water introduction to the fluoride emission abatement system 300. In certain embodiments, when concentration of fluoride gas detected at the fluoride ion clean tool 200 is over about 1.0 ppm., the water flow controller 100 increases water introduction to the fluoride emission abatement system 300 so as to reduce fluoride compound contamination on the environment.

In some embodiments in accordance with the present disclosure, the sensor 314 is a fluoride concentration sensor arranged at the foreline 202. The sensor 314 is configured to detect concentration of fluoride gas released from the fluoride ion clean tool 200. The concentration is transmitted to the water flow controller 100 for processing. Based on the processing result, the water introduction to the fluoride emission abatement system 300 is adjusted. For example, if the fluoride concentration at the foreline 202 is over a predetermined value, the computing unit 104 determines that the fluoride ion clean tool 200 is in clean operation. Accordingly, more water is allowed to the fluoride emission abatement system 300 to process the excess fluoride gas from the fluoride ion clean tool 200.

In some embodiments in accordance with the present disclosure, the water flow controller 100 is arranged at the fluoride emission abatement system 300, as depicted in FIG. 2B. In certain embodiments, the water flow controller 100 is arranged at the fluoride ion clean tool 200, as depicted in FIG. 2C. Alternatively, the water flow controller 100 is arranged at any position in the system 10 deemed reasonable to persons having ordinary skill in the art.

Referring to FIG. 2C, in some embodiments, the water flow controller 100 is arranged at the fluoride ion clean tool 200. The controller 100 receives electrical signals with ambient condition at the fluoride ion clean tool 200 from the sensor 212 and processes such ambient condition by the processor 104. The transmitter 106 sends the processing result to an actuator 306 of a valve 304 so as to adjust water introduction to the fluoride emission abatement system 300. In certain embodiments, the system 10 has a first valve 304 and a second valve 304′. Water is introduced continuously to the fluoride emission abatement system 300 through the second valve 304′. On the other hand, the first valve 304 is manipulated by the water flow controller 100 so as to adjust water introduction through the first valve 304. For example, when the fluoride ion clean tool 200 is in a clean mode, more water is needed to process the excessive fluoride gas at the fluoride emission abatement system 300. Therefore, water is allowed to flow through both the first valve 304 and the second valve 304′. On the other hand, when the fluoride ion clean tool 200 is in normal operation, less water is needed to process the fluoride gas at the fluoride emission abatement system 300. Therefore, water is not allowed to flow through the first valve 304. Accordingly, water introduction to the fluoride emission abatement system 300 is controlled based on the processing status of the fluoride ion clean tool 200. In certain embodiments, the valves 304, 304′ can be adjusted manually. For example, a processing status of the fluoride ion clean tool 200 is displayed at a panel of the fluoride ion clean tool 200 or the water flow controller 100. Based on the information displayed, technicians of the fabrication plant adjust the valve 304, 304′ to manipulate water introduction to the fluoride emission abatement system 300. In some embodiments, the valves 304, 304′ are on/off valves, which are easier for technicians to operate.

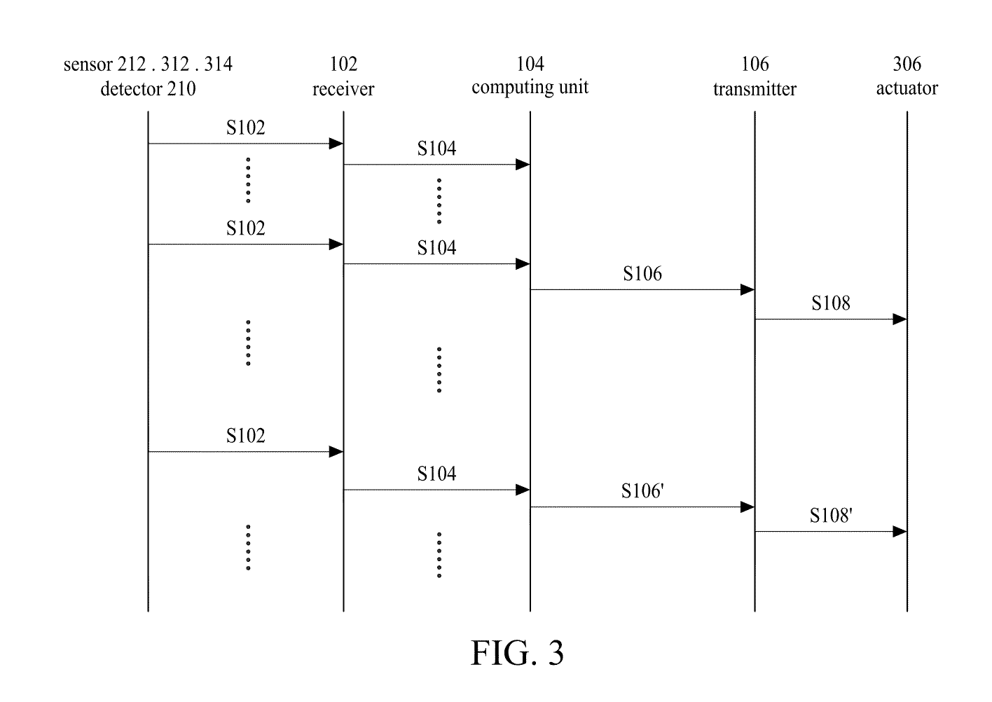

FIG. 3 illustrates communications between components in a system including a water flow controller in accordance with some embodiments of the present disclosure.

Referring to FIG. 3, the detector 210/sensor 212, 312, 314 continue to detect a processing status of the fluoride ion clean tool or an ambient condition in the system 10 (collectively the “operation information”). In step S102, the operation information is transmitted to the receiver 102. In step S104, the operation information is transmitted to the computing unit 104. Accordingly, the computing unit 104 processes the operation information and compares the operation information with some predetermined values, such as, fluoride compound gas concentration, pressure or flow rate. If the processing result indicates that the processing status of the fluoride ion clean tool is not changed, the computing unit 104 ignores the latest operation information and continues to process the next one. If the processing result indicates that the processing status of the fluoride ion clean tool is changed, for example, from a normal operation to a clean operation, in operation S106, the computing unit 104 sends a command to the transmitter 106. In operation S108, The transmitter 106 relays the command to the actuator 306. As a result, the water flow controller manipulates water introduction to the fluoride ion clean tool based on the processing status of the fluoride ion clean tool.

In some embodiments in accordance with the present disclosure, operations S102 and S104 are repeated continuously. In other words, latest operation information continues to be sent to the computing unit 104 through the receiver 102. The computing unit 104 does not send out commands to adjust the actuator 306 until the computing unit 104 determines that a processing status of the fluoride ion clean tool has changed. For example, when the computing unit 104 determines that the fluoride ion clean tool has changed from a clean operation to a normal operation, in operation S106′, a command to adjust the actuator 306 is sent through the transmitter 106. In operation S108′, the command to reduce the water flow rate running through the valve is transmitted to the actuator 306. Accordingly, the water flow controller reduces water introduction to the fluoride emission abatement system based on the operation information of the fluoride ion clean tool.

In some embodiments in accordance with the present disclosure, the processing status of the fluoride ion clean tool is not limited to normal operation and clean operation. For example, the fluoride ion clean tool further has an idle mode, during which no operation is performed at the fluoride ion clean tool. In certain embodiments, the water flow controller is configured to provide different kinds of configuration in response to different processing statuses of the fluoride ion clean tool.

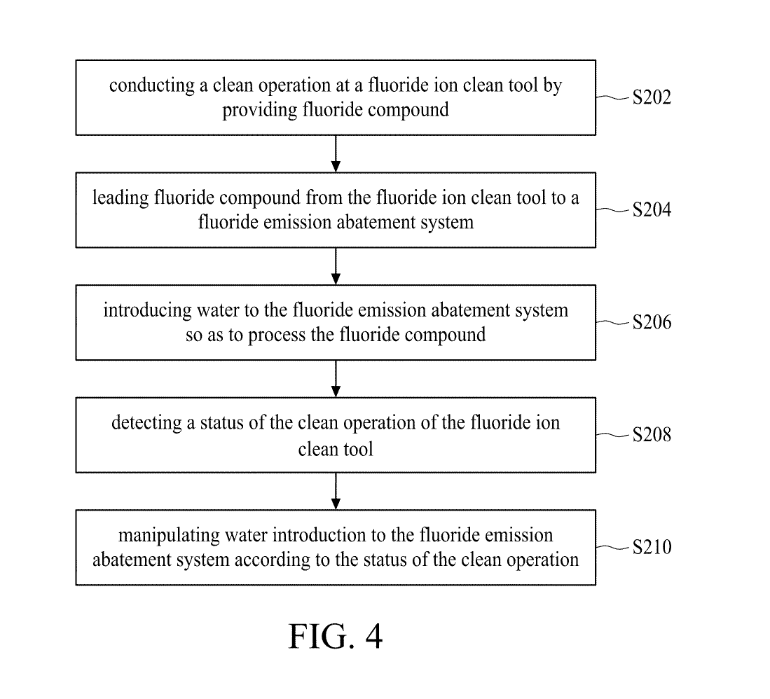

FIG. 4 is a flow diagram of a method for manufacturing semiconductor wafer in accordance with some embodiments of the present disclosure.

Referring to FIG. 4, in operation S202, fluoride gas is provided at the fluoride ion clean tool to conduct a clean operation. In operation S204, the fluoride gas is lead out from the fluoride ion clean tool and to a fluoride emission abatement system. In operation S206, water is introduced to the fluoride emission abatement system so as to process the fluoride gas. In some embodiments, after the fluoride gas is processed, liquid HF is generated. In operation S208, a status of the clean operation of the fluoride ion clean tool is detected. In operation S210, based on the status of the clean operation, water introduction to the fluoride emission abatement system is manipulated. In certain embodiments, when the fluoride ion clean tool is in the clean operation, i.e., when more fluoride gas is introduced to the fluoride ion clean tool, more water is provided to the fluoride emission abatement system to process the excess fluoride gas. The various operations of FIG. 4 are discussed below in more detail in association with behavioral views corresponding to the operations of the flow diagram.

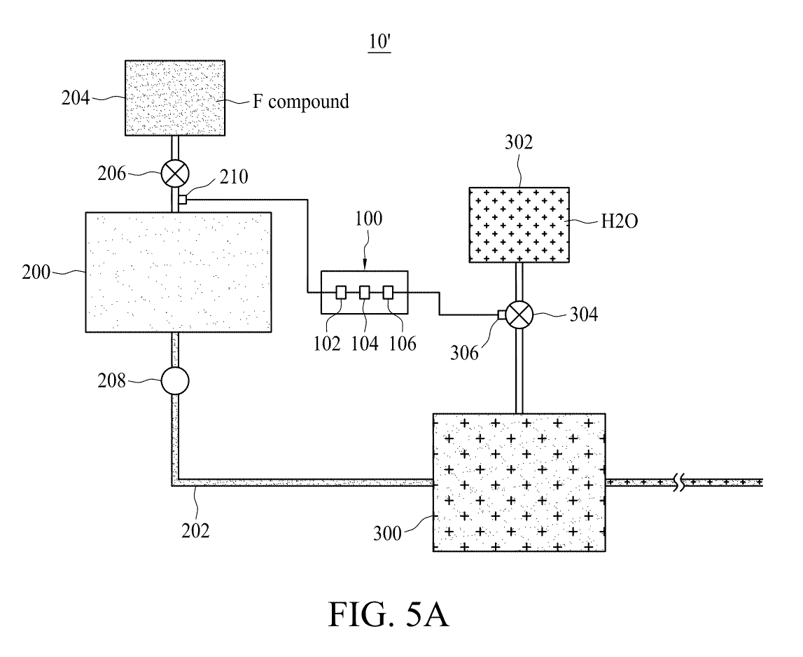

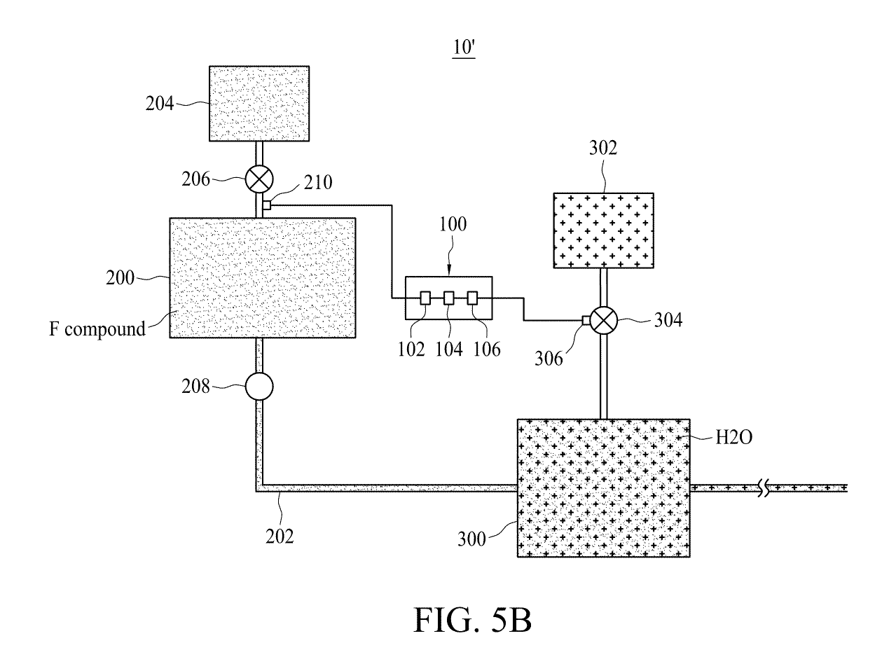

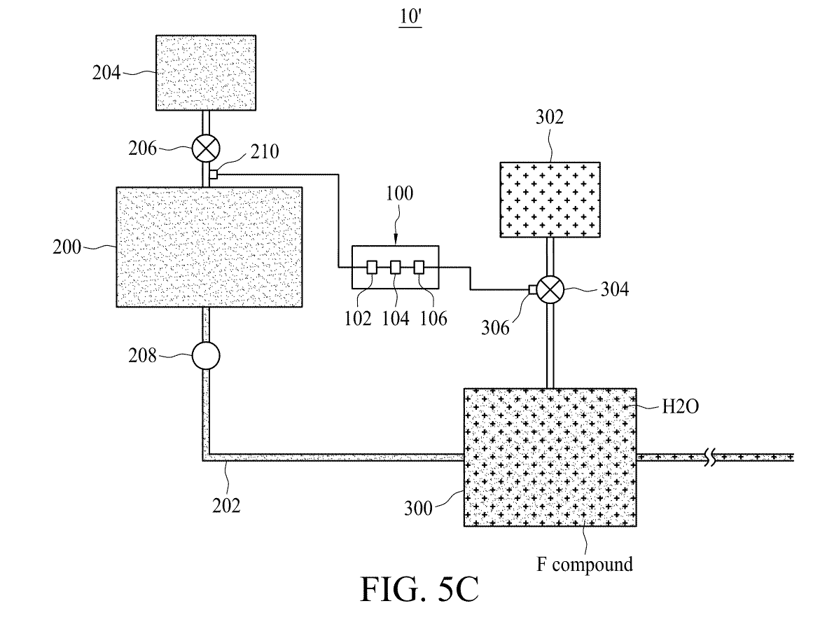

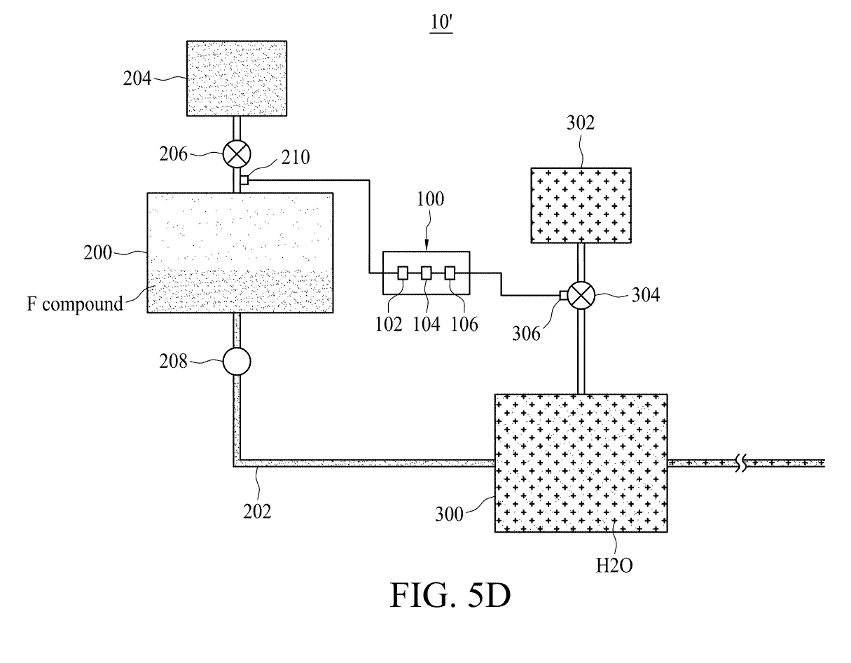

FIGS. 5A to 5D are behavioral views of an apparatus in various stages corresponding to the method of FIG. 4.

In FIG. 5A, the fluoride ion clean tool 200 is in normal operation. In some embodiments, the fluoride ion clean tool 200 is a chemical vapor deposition (CVD) tool at this stage. No or only little fluoride gas is introduced to the fluoride ion clean tool 200. In addition, only little water is introduced to the fluoride emission abatement system 300 for purposes of cooling, maintaining steam concentration or others. Processing status of the fluoride ion clean tool 200 is transmitted in the form of electronic signals from the detector 210 or other detectors to the water flow processor 100. Alternatively, flow rate of the fluoride gas is recorded as an indicator of the processing status of the fluoride ion clean tool 200. In certain embodiments, water introduction to the fluoride emission abatement system 300 is maintained at a certain flow rate when the processing status of the fluoride ion clean tool 200 is not changed.

In FIG. 5B, the fluoride ion clean tool 200 is in clean operation. In other words, fluoride gas is introduced to the fluoride ion clean tool 200 from the gas source 204 through the valve 206. A detector captures the status of the clean operation of the fluoride ion clean tool 200 and sends an electrical signal to the water flow controller 100. Alternatively, the detector 210 captures a flow rate of fluoride gas introduced to the fluoride ion clean tool 200 and transmits such information to the water flow controller 100. The computing unit 104 of the water flow controller 100 processes the electrical signal and generates a result. Based on the result, a command is sent to the actuator 306 of the valve 304. Accordingly, the valve is opened and water is introduced to the fluoride emission abatement system 300 at a certain flow rate. In certain embodiments, the water flow controller 100 is configured to provide more water to the fluoride emission abatement system 300 right after the status of the clean operation is changed. In other words, water is pre-introduced to the fluoride emission abatement system 300 awaiting fluoride gas from the fluoride ion clean tool 200.

In some embodiments in accordance with the present disclosure, ambient condition in the system 10 is detected to be used as water adjustment bases for the water flow controller 100. For example, ambient condition at the fluoride ion clean tool 200 or the fluoride emission abatement system 300 is detected by a sensor (not depicted). In some embodiments, the sensor is a chemical sensor for detecting fluoride gas concentration at the fluoride ion clean tool 200. A fluoride concentration over a predetermined value indicates that the fluoride ion clean tool 200 is in clean operation. The computing unit 104 generates a processing result and sends a command to the actuator 306 through the transmitter 106. Accordingly, the water flow controller 100 adjusts the actuator 306 and allows more water to be introduced to the fluoride emission abatement system 300. In certain embodiments, the sensor is a flow meter for detecting flow rate of fluoride gas introduced to the fluoride emission abatement system 300. A flow rate lower than a predetermined value indicates that the fluoride ion clean tool 200 is not in clean operation. Accordingly, the water flow controller 100 adjusts the actuator 306 and reduces water introduction to the fluoride emission abatement system 300.

In FIG. 5C, the fluoride ion clean tool 200 continues to be cleaned. In addition, the fluoride gas lead out of the fluoride ion clean tool 200 has reached the fluoride emission abatement system 300. Because water has been pre-introduced to the fluoride emission abatement system 300, fluoride gas are more thoroughly processed by and reacted with water. Accordingly, less fluoride compounds, such as F2, NF3, C2F6 or SiF4, will be released to the environment. In some embodiments, the water flow controller 100 continues to receive electrical signals from the detector 210 or other sensors. Accordingly, the water flow controller 100 determines whether the status of the clean operation of the fluoride ion clean tool 200 maintains the same. If so, the flow rate of water introduction to the fluoride emission abatement system 300 will be maintained.

In FIG. 5D, fluoride gas introduction to the fluoride ion clean tool 200 is reduced to little or zero. In other words, the fluoride ion clean tool 200 is now not in the clean operation. Electrical signals representing processing status of the fluoride ion clean tool 200 is transmitted to the water flow controller 100 from the sensor 210 or other detectors. After the computing unit 104 determines that the processing status of the fluoride ion clean tool 200 has changed, water introduction to the fluoride emission abatement system 300 is adjusted. In certain embodiments, the flow rate of water introduction to the fluoride emission abatement system 300 is maintained for a specific period to ensure that residue fluoride gas from the fluoride ion clean tool 200 are fully processed.

In some embodiments in accordance with the present disclosure, a processing status of one or more semiconductor wafer process tools or stages in the same fabrication plant is transmitted to the water flow controller 100. Based on such information, the water flow controller 100 manipulates water introduction to the fluoride emission abatement system 300. For example, when one semiconductor wafer process tool or stage in the same fabrication plant is in a water-poor condition (i.e. requires more water), the water flow controller 100 reduces water introduction to the fluoride emission abatement system 300 to accommodate such needs. In certain embodiments, the water flow controller 100 transmits the water-poor condition to the fluoride ion clean tool 200. Accordingly, the fluoride ion clean tool 200 will not enter into the clean operation due to the insufficient amount of water available at the water source 302.

In some embodiments, a system includes a fluoride ion clean tool connected with a fluoride emission abatement system through a foreline is provided. The system further includes a water flow controller arranged to transmit electrical signals between the fluoride ion clean tool and the fluoride emission abatement system. Fluoride gas is introduced to the fluoride ion clean tool for clean process. Thereafter, fluoride gas is released from the fluoride ion clean tool and lead to the fluoride emission abatement system. In addition, water is introduced to the fluoride emission abatement system so as to process the fluoride gas. The water-processed fluoride compound poses less contamination on the environment.

In some embodiments, the water flow controller includes a receiver connected with a computing unit. The receiver accepts electrical signals from a detector in the system. The detector in configured to measure a flow rate of fluoride gas introduced to the fluoride ion clean tool. The computing unit processes the electrical signals to reach a result. Based on the processing result of the computing unit, a transmitter sends commends to an actuator of the fluoride emission abatement system so as to adjust water introduced to the fluoride emission abatement system.

In some embodiments, the fluoride ion clean tool is part of a semiconductor wafer process tool, an integrated circuit process tool, a liquid-crystal display process tool or a light-emitting diode process tool.

In some embodiments, the water flow controller manipulates water introduction to the fluoride emission abatement system at a first water flow rate when fluoride gas is introduced to the fluoride ion clean tool at a first flow rate. In addition, the water flow controller manipulates water introduction to the fluoride emission abatement system at a second water flow rate when fluoride gas is introduced to the fluoride ion clean tool at a second flow rate. When the first flow rate is higher than the second flow rate, the first water flow rate is higher than the second water flow rate. In certain embodiments, the first water flow rate is between 8 LPM and about 12 LPM, and the second water flow rate is between about 0 and about 5 LPM.

In some embodiments, when the flow rate of fluoride gas introduced to the fluoride ion clean tool is above a predetermined value, the water flow controller increases water introduction to the fluoride emission abatement system.

In some embodiments, the water flow controller is connected with a central control unit of a fabrication plant facilitating the system. The water flow controller receives from the central control unit a signal of processing status of semiconductor wafer processing tools within the fabrication plant. In certain embodiments, the water flow controller manipulates water introduction to the fluoride emission abatement system according to the signal transmitted from the central control unit.

In some embodiments, the detector is a flow meter arranged at the fluoride emission abatement system for measuring a flow rate of fluoride compound at the fluoride emission abatement system.

In some embodiments, the water flow controller is connected with a sensor. The sensor detects an ambient condition in the system and transmits the ambient condition to the water flow controller. Based on the ambient condition, the water flow controller manipulates water introduction to the fluoride emission abatement system. In certain embodiments, the sensor is a pressure sensor for detecting a pressure in the fluoride emission abatement system.

In some embodiments, the sensor is a chemical sensor for detecting concentration of fluoride gas in the fluoride ion clean tool. In certain embodiments, the fluoride gas includes F2, NF3, C2F6 or SiF4. In some embodiments, the water flow controller increases the water introduction to the fluoride emission abatement system when concentration of the fluoride gas is over about 1.0 ppm.

In some embodiments, a system having a fluoride ion clean tool connected with a fluoride emission abatement system through a foreline is provided. Fluoride gas is used at the fluoride ion clean tool for cleaning, and released to the fluoride emission abatement system. Water is introduced to the fluoride emission abatement system from a water source so as to process the fluoride gas. The fluoride emission abatement system is connected with a waste processor, and fluoride gas released from the fluoride ion clean tool is lead to the waste processor after being processed by the fluoride emission abatement system.

In some embodiments, a water flow controller is provided at the system. The water flow controller is connected with an actuator, which is configured to control water introduction from the water source to the fluoride emission abatement system. The water flow controller includes a receiver for accepting electrical signals from a detector. The detector is arranged to measure a concentration of fluoride compound at the waste processor. In addition, a computing unit is arranged to process the electrical signals from the detector to reach a result. Based on the processing result of the computing unit, a transmitter sends commends to the actuator so as to adjust water introduced to the fluoride emission abatement system.

In some embodiments, the fluoride ion clean tool includes a chemical vapor deposition (CVD) process chamber.

In some embodiments, the water flow controller is arranged to adjust water introduction to the fluoride emission abatement system based on a gas flow rate detected at the waste processor.

In some embodiments, a method for manufacturing semiconductor wafer is provided. A clean operating at a fluoride ion clean tool is conducted by providing fluoride gas to the fluoride ion clean tool. The fluoride gas is lead from the fluoride ion clean tool to a fluoride emission abatement system. Water is introduced to the fluoride emission abatement system so as to process the fluoride gas. Status of the clean operation of the fluoride ion clean tool is detected. Based on the status of the clean operation, water introduction to the fluoride emission abatement system is adjusted.

In some embodiments, an ambient condition at the fluoride ion clean tool is detected. In certain embodiments, the ambient condition is compared with a predetermined value, and a comparison result is generated accordingly. Based on the comparison result, water introduction to the fluoride emission abatement system is manipulated.

In some embodiments, a processing status from a different semiconductor wafer process system is received. Based on the processing status of the different semiconductor wafer process system, water introduction to the fluoride emission abatement system is manipulated.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A system, comprising:
a water flow controller arranged to transmit electrical signals between a fluoride ion clean tool and a fluoride emission abatement system, wherein the fluoride emission abatement system is connected with the fluoride ion clean tool through a foreline,
wherein fluoride gas is configured to be released from the fluoride ion clean tool and lead to the fluoride emission abatement system,
wherein water is introduced to the fluoride emission abatement system so as to process the fluoride gas,
wherein the water flow controller includes:
a receiver for accepting electrical signals from a detector, wherein the detector measures a flow rate of fluoride gas introduced to the fluoride ion clean tool;
a computing unit for processing the electrical signals from the detector; and
a transmitter for sending commands to an actuator of the fluoride emission abatement system so as to adjust water introduced to the fluoride emission abatement system based on a processing result of the computing unit.

2. The system according to claim 1, wherein the fluoride ion clean tool is part of a semiconductor wafer process tool, an integrated circuit process tool, a liquid-crystal display process tool or a light-emitting diode process tool.

3. The system according to claim 1, wherein the water flow controller is configured to manipulate water introduction to the fluoride emission abatement system at a first water flow rate when fluoride gas is introduced to the fluoride ion clean tool at a first flow rate, and at a second water flow rate when fluoride gas is introduced to the fluoride ion clean tool at a second flow rate,
wherein when the first flow rate is higher than the second flow rate, the first water flow rate is higher than the second water flow rate.

4. The system according to claim 3, wherein the first water flow rate is between 8 LPM and about 12 LPM, and the second water flow rate is between about 0 and about 5 LPM.

5. The system according to claim 1, wherein the water flow controller is configured to increase the water introduction to the fluoride emission abatement system when the flow rate of fluoride gas introduced to the fluoride ion clean tool is above a predetermined value.

6. The system according to claim 1, wherein the water flow controller is connected with a central control unit of a fabrication plant facilitating the system, wherein the water flow controller is configured to receive from the central control unit a signal of processing status of semiconductor wafer processing tools within the fabrication plant.

7. The system according to claim 6, wherein the water flow controller is configured to manipulate the water introduction to the fluoride emission abatement system according to the signal transmitted from the central control unit.

8. The system according to claim 1, wherein the detector is a flow meter at the fluoride emission abatement system.

9. The system according to claim 1, wherein the water flow controller is connected with a sensor,
wherein the water flow controller is configured to receive an ambient condition from the sensor and accordingly manipulate the water introduction to the fluoride emission abatement system.

10. The system according to claim 9, wherein the sensor is a pressure sensor configured to detect a pressure in the fluoride emission abatement system.

11. The system according to claim 9, wherein the sensor is a chemical sensor configured to detect concentration of fluoride gas in the fluoride ion clean tool.

12. The system according to claim 11, wherein the fluoride gas includes F2, NF3, C2F6 or SiF4.

13. The system according to claim 11, wherein the water flow controller is configured to increase the water introduction to the fluoride emission abatement system when concentration of the fluoride gas is over about 1.0 ppm.

14. A system, comprising:
a fluoride ion clean tool connected with a fluoride emission abatement system through a foreline, wherein the fluoride emission abatement system is connected with a waste processor, wherein fluoride gas released from the fluoride ion clean tool is lead to the waste processor after being processed by the fluoride emission abatement system,
wherein water is introduced to the fluoride emission abatement system from a water source so as to process the fluoride gas; and
a water flow controller connected with an actuator so as to control water introduction to the fluoride emission abatement system,
wherein the water flow controller comprises:
a receiver for accepting electrical signals from a detector, wherein the detector measures a concentration of fluoride compound at the waste processor;
a computing unit for processing the electrical signals from the detector; and
a transmitter for sending commands to the actuator so as to adjust water introduced to the fluoride emission abatement system based on a processing result of the computing unit.

15. The system according to claim 14, wherein the fluoride ion clean tool includes a chemical vapor deposition (CVD) process chamber.

16. The system according to claim 14, wherein the water flow controller adjusts water introduction to the fluoride emission abatement system based on a gas flow rate detected at the waste processor.

17. A method for manufacturing semiconductor wafer, comprising:
conducting a clean operation at a fluoride ion clean tool by providing fluoride gas;
leading fluoride gas from the fluoride ion clean tool to a fluoride emission abatement system;
introducing water to the fluoride emission abatement system so as to process the fluoride gas;
detecting a status of the clean operation of the fluoride ion clean tool; and
manipulating water introduction to the fluoride emission abatement system according to the status of the clean operation.

18. The method for manufacturing semiconductor wafer according to claim 17, further comprising:
detecting an ambient condition at the fluoride ion clean tool.

19. The method for manufacturing semiconductor wafer according to claim 18, further comprising:
comparing the ambient condition with a predetermined value and generating a comparison result; and
manipulating water introduction to the fluoride emission abatement system according to the comparison result.

20. The method for manufacturing semiconductor wafer according to claim 17, further comprising:
receiving a processing status from a different semiconductor wafer process system; and
manipulating water introduction to the fluoride emission abatement system according to the processing status of the different semiconductor wafer process system.
